(19) United States
(12) Patent Application Publication
(10) Pub. No.: US 2017/0263645 A1
(43) Pub. Date: Sep. 14, 2017

(54) SUBSTRATE, MANUFACTURING METHOD THEREOF, AND DISPLAY DEVICE

(71) Applicant: BOE TECHNOLOGY GROUP CO., LTD., Beijing (CN)

(72) Inventors: Fengjuan LIU, Beijing (CN); Meili WANG, Beijing (CN)

(21) Appl. No.: 15/283,517

(22) Filed: Oct. 3, 2016

(30) Foreign Application Priority Data
Mar. 10, 2016 (CN) 201610136488.X

(51) Int. Cl. H01L 27/12

(52) U.S. Cl. CPC H01L 27/124; H01L 27/1262; H01L 27/1248

(57) ABSTRACT

A substrate comprising a base, and a copper metallic layer and a first barrier layer disposed on the base in sequence, and further comprising a connecting layer positioned on the first barrier layer; the connecting layer is configured to connect photoresist coated on the connecting layer and the first barrier layer.

### TECHNICAL FIELD

Embodiments of the present disclosure relate to a substrate, a manufacturing method thereof, and a display device.

### BACKGROUND

At present, as screen sizes become larger, more and more display devices require a copper (Cu) metallic layer as a conductive layer. It is necessary to deposit a barrier layer for preventing Cu diffusion over/beneath the Cu metallic layer. Material of the barrier layer can be molybdenum-niobium alloy (MoNb), so that a structure of dual-layer such as Cu/MoNb or a structure of tri-layer such as MoNb/Cu/MoNb is usually formed. The structure of Cu/MoNb (two-layered) has a better etching effect, but the Cu conductive layer at the top will be exposed and will be inclined to be oxidized and diffused, while the structure of MoNb/Cu/MoNb (tri-layered) can prevent oxidation and diffusion well and can help to prolong the life of the device.

However, in the practical process of the structure of MoNb/Cu/MoNb (tir-layered), result of patterning the three-layered structure is not ideal and phenomenon of ununiform pattern of the upper MoNb barrier layer is obvious. Even before a process of peeling off photoresist is not carried out, it can be observed that the upper MoNb barrier layer falls off together with the photoresist which results in serious distribution unevenness of metallic layers and even surface oxidation. By changing material of the photoresist, the etching result is improved slightly, but the effect is limited. It is largely due to poor adherence between the photoresist and the upper MoNb barrier layer. In the process of hard bake of the photoresist, as shown in FIG. 1a, the edge of the photoresist 01 will be curled; or as shown in FIG. 1b, a part of or a large part of the photoresist 01 falls off. And then, after etching the three metallic layers MoNb/Cu/MoNb and before peeling off the photoresist, as shown in FIG. 2a, contraction of the upper MoNb barrier layer 02 will be serious; or as shown in FIG. 2b, the upper MoNb barrier layer 02 will fall off along with the photoresist 01 and only the MoNb barrier layer 03 located on the surface of the base 03 and a copper metallic layer 05 located on the surface of the MoNb barrier layer 04 are remained.

### SUMMARY

At least one embodiment of the disclosure provides a substrate comprising a base, and a copper metallic layer and a first barrier layer disposed on the base in sequence, wherein the substrate further comprises:

a connecting layer positioned on the first barrier layer; the connecting layer is configured to connect photoresist coated on the connecting layer and the first barrier layer.

At least one embodiment of the disclosure provides a method for manufacturing the substrate according to claim 1, comprising:

depositing a copper metallic layer film, a first barrier layer film and a connecting layer film in sequence on a base;

performing a patterning process on the copper metallic layer film, the first barrier layer film and the connecting layer film so as to form patterns of a copper metallic layer, a first barrier layer and a connecting layer; the connecting layer being configured to connect photoresist coated on the connecting layer and the first barrier layer.

At least one embodiment of the disclosure provides a display device, which comprises the substrate described-above.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1a and FIG. 1b are illustrative structural views after patterning the photoresist on the substrate in the conventional art;

FIG. 2a and FIG. 2b are illustrative structural views after patterning the three layered metallic layers on the substrate in the conventional art;

FIG. 3 is an illustrative structural view of a substrate according to one embodiment of the present disclosure;

FIG. 4 is an illustrative structural view of a substrate according to another embodiment of the present disclosure;

FIG. 5 is an illustrative structural view of a substrate according to yet another embodiment of the present disclosure;

FIG. 6 is a flow chart of a method for manufacturing substrate according to one embodiment of the present disclosure;

FIG. 7 is a flow chart of a method for manufacturing substrate according to another embodiment of the present disclosure;

FIG. 8 is a flow chart of a method for manufacturing substrate according to yet another embodiment of the present disclosure;

FIG. 9 is a flow chart of a method for manufacturing substrate according to still another embodiment of the present disclosure; and

FIG. 10a to FIG. 10f are illustrative structural views after respective steps are performed in the method for manufacturing substrate according to one embodiment of the present disclosure.

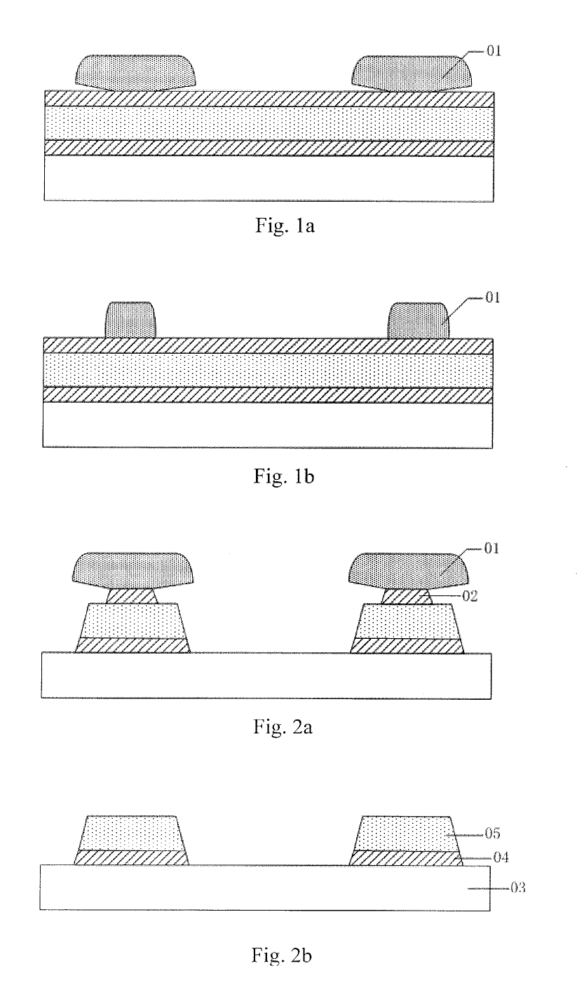

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

In the drawings, thicknesses and shapes of film layers are not actual scales of the substrate, but are only intended to illustrate the present disclosure.

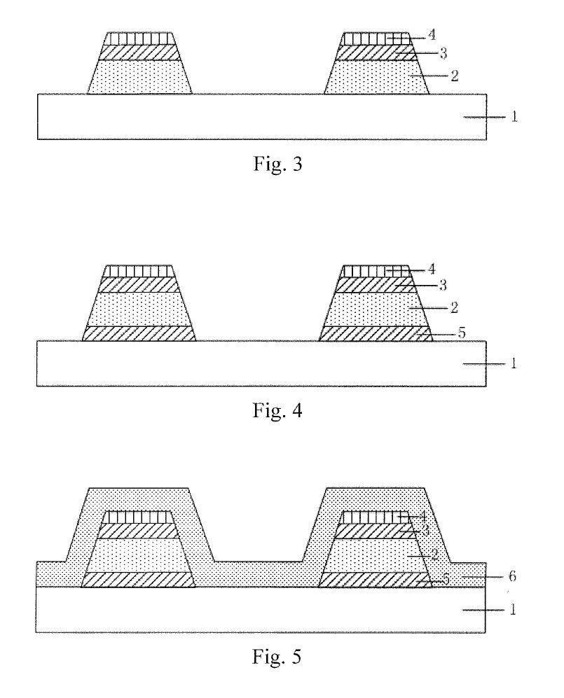

At least one embodiment of the present disclosure provides a substrate. As illustrated in FIG. 3, the substrate comprises a base 1, and a copper metallic layer 2 and a first barrier layer 3 disposed on the base 1 in sequence. The substrate further comprise a connecting layer 4 positioned on the first barrier layer 3. The connecting layer 4 is configured to connect photoresist coated on the connecting layer 4 and the first barrier layer 3.

In the above-described substrate according to embodiments of the present disclosure, since a connecting layer is disposed on the first barrier layer and is configured to connect the photoresist coated on the connecting layer and the first barrier layer, the adherence between the first barrier layer and the photoresist can be improved, thereby solving the problem of ununiform pattern in the patterning process performed on the film layers on the substrate and improving the patterning.

It is to be noted that the above-described substrate can be any substrate for display, which can be for example a color filter substrate, an array substrate or a touch screen and the like, which is formed with a copper metallic layer as a conductive layer.

In one embodiment of the present disclosure, the connecting layer is made of at least one of silicon oxide, silicon nitride, or silicon oxynitride. The material of the connecting layer can be selected according to actual practice, and is not restricted herein as long as the material of the connecting layer can be subjected to dry etching and have a higher wet etching selection ratio with respect to copper.

In one embodiment of the present disclosure, the first barrier layer disposed on the copper metallic layer can prevent oxidation and diffusion of the copper metallic layer. To further prevent oxidation and diffusion of the copper metallic layer, the substrate can further comprise a second barrier layer 5 positioned between the base 1 and the copper metallic layer 2, as illustrated in FIG. 4.

In one embodiment of the present disclosure, as illustrated in FIG. 5, the substrate can further comprise an insulating layer 6 covering the connecting layer 4. FIG. 5 illustrates that the insulating layer 6 can completely cover the second barrier layer 5, the copper metallic layer 2, the first barrier layer 3 and the connecting layer 4 and has a protection and insulation function.

Further, in one embodiment of the present disclosure, material of the insulating layer 6 can comprise at least one of silicon oxide (SiOx), silicon nitride (SiNx), or silicon oxynitride (SiON). The material of the insulating layer can be selected to be close to or similar to material of the connecting layer so as to effectively prevent any influence on the performance of other film layers.

In one embodiment of the present disclosure, at least one of the first barrier layer and the second barrier layer can be made of molybdenum alloy material, so as to effectively prevent oxidation and diffusion of the copper metallic layer. The molybdenum alloy material can comprise one of molybdenum-niobium alloy (MoNb), molybdenum-tungsten alloy (MoWu), molybdenum-titanium alloy (MoTi) and molybdenum zirconium alloy (MoZr) and a combination thereof. These materials have a relatively high chemical resistance and can further prevent the copper metallic layer from being corroded by the etching solution for patterning.

In one embodiment of the present disclosure, the copper metallic layer can comprise at least one of a gate electrode, a source electrode, a drain electrode, a gate line connected with the gate electrode, a data line connected with the source electrode, an anode and a cathode in an organic light emitting device, or an electrode lead commonly used in the field of display and etc. The above-described base can be any base on which the copper metallic layer is formed. The base can be a base comprising other functional film layers or can be a base without any functional film layer, such as a glass substrate and the like. Taking an example of the copper metallic layer comprising a gate electrode, if TFT is a bottom-gate type TFT, then the gate electrode can be directly formed on the glass substrate or can be disposed on the glass substrate having a buffer layer, while if TFT is a top-gate type TFT, then the gate electrode can be formed on a glass substrate on which film layers such as a source electrode, a drain electrode and an active layer have been already formed. The base is a concept relative to the gate electrode, and the structure except the gate electrode can be understood as the base.

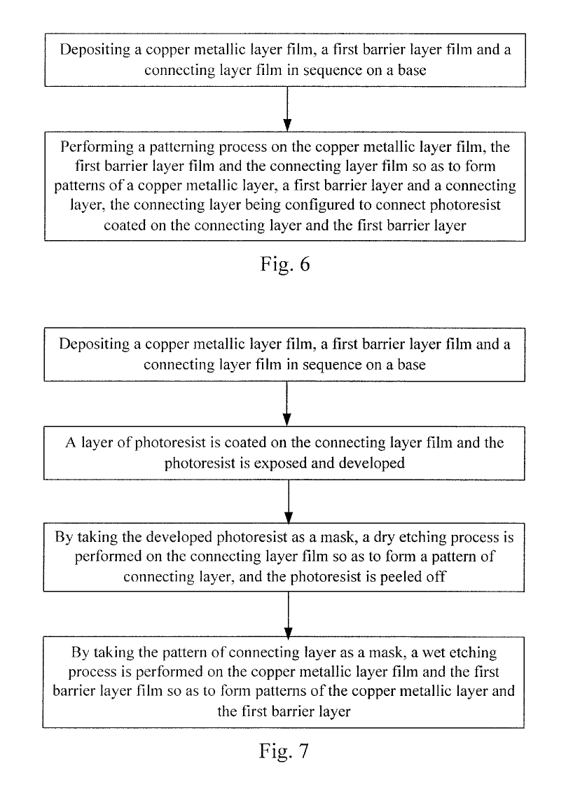

At least one embodiment of the present disclosure provides a method for manufacturing the above-described substrate, as illustrated in FIG. 6, which comprises:

depositing a copper metallic layer film, a first barrier layer film and a connecting layer film in sequence on a base;

performing a patterning process on the copper metallic layer film, the first barrier layer film and the connecting layer film so as to form patterns of a copper metallic layer, a first barrier layer and a connecting layer, the connecting layer being configured to connect photoresist coated on the connecting layer and the first barrier layer.

In the method according to embodiments of the present disclosure, the connecting layer film is firstly formed on the first barrier layer film and then the patterns of the copper metallic layer, the first barrier layer and the connecting layer are formed by the patterning process. When the patterning process is performed, the connecting layer is provided to enhance the adherence between the first barrier layer and the photoresist, so as to solve the problem of ununiform pattern in the patterning process performed on the film layers on the substrate and improving the patterning effect.

In one embodiment of the present disclosure, forming patterns of a copper metallic layer, a first barrier layer and a connecting layer is achieved in the following manner.

As illustrated in FIG. 7, firstly, a layer of photoresist is coated on the connecting layer film and the photoresist is exposed and developed. Thereafter, by taking the developed photoresist as a mask, a dry etching process is performed on the connecting layer film so as to form a pattern of connecting layer, and the photoresist is peeled off. And then, by taking the pattern of connecting layer as a mask, a wet etching process is performed on the copper metallic layer film and the first barrier layer film so as to form patterns of the copper metallic layer and the first barrier layer.

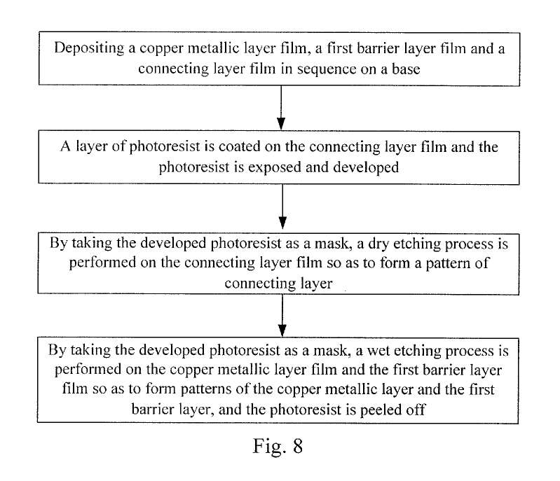

Alternatively, patterns of a copper metallic layer, a first barrier layer and a connecting layer can be formed by the flow as illustrated in FIG. 8.

As illustrated in FIG. 8, firstly, a layer of photoresist is coated on the connecting layer film and the photoresist is exposed and developed. Thereafter, by taking the developed photoresist as a mask, a dry etching process is performed on the connecting layer film so as to form a pattern of connecting layer. Next, by taking the developed photoresist as a mask, a wet etching process is performed on the copper metallic layer film and the first barrier layer film so as to form patterns of the copper metallic layer and the first barrier layer, and the photoresist is peeled off.

In the above two manufacturing methods, there is no additional patterning process required and compatibility with subsequent processes is good. It is to be noted that a cleaning process is required after the wet etching process is performed on the copper metallic layer film and the first barrier layer film.

In one embodiment of the present disclosure, after forming patterns of the copper metallic layer and the first barrier layer by taking the pattern of connecting layer as a mask and performing a wet etching process on the copper metallic layer film and the first barrier layer film, or after forming patterns of the copper metallic layer and the first barrier layer by taking the developed photoresist as a mask and performing a wet etching process on the copper metallic layer film and the first barrier layer film and peeling off the photoresist, the method further comprises: forming a pattern of insulating layer on a substrate formed with the pattern of connecting layer.

In one embodiment of the present disclosure, to further prevent oxidation and diffusion of the copper metallic layer, before depositing the copper metallic layer film on the base, the substrate manufacturing method can further comprise depositing a second barrier layer film on the base; after forming a pattern of copper metallic layer, the method can further comprise performing a patterning process on the second barrier layer film so as to form a pattern of second barrier layer.

In one embodiment of the present disclosure, patterns of the second barrier layer, the copper metallic layer and the first barrier layer can be formed by one patterning process. For example, taking the pattern of connecting layer as a mask, one wet etching process is performed on the second barrier layer film, the copper metallic layer film and the first barrier layer film, thereby forming patterns of the second barrier layer, the copper metallic layer and the first barrier layer.

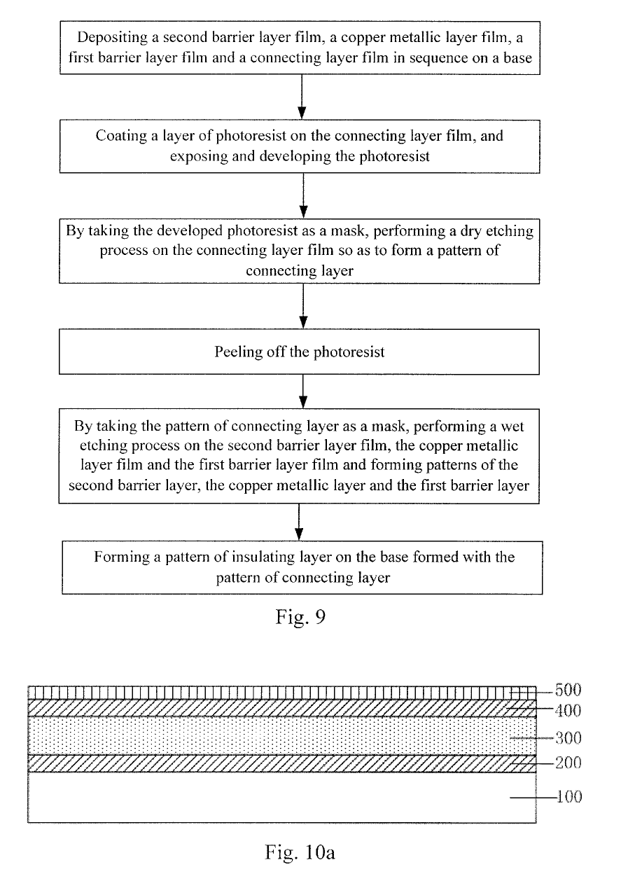

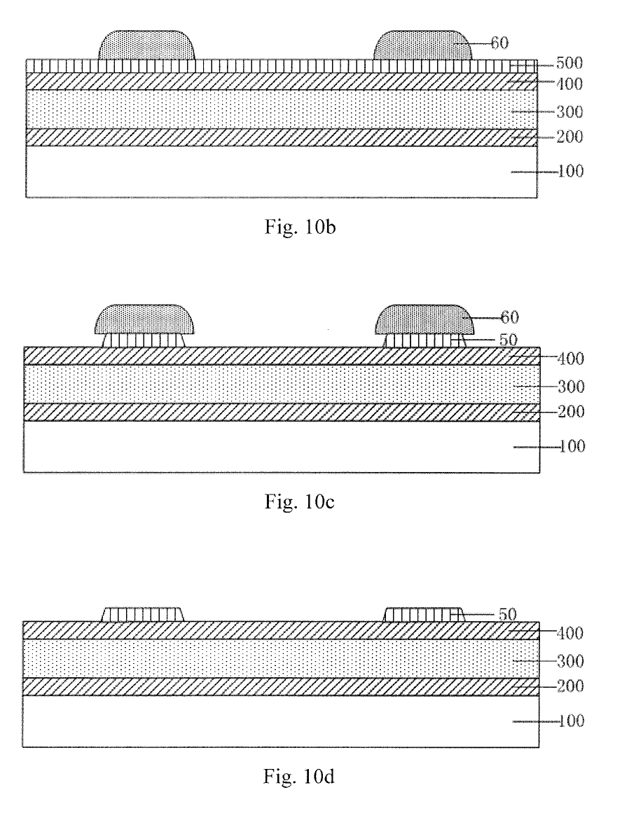

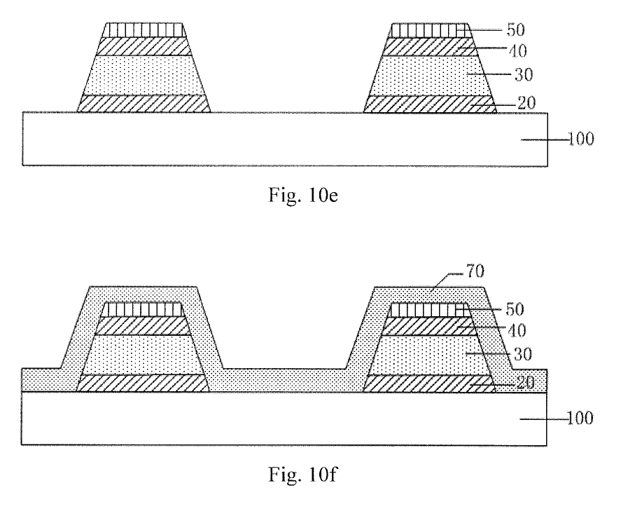

With reference to FIG. 9 and FIG. 10, a substrate manufacturing method according to one embodiment of the present disclosure is described below.

As illustrated in FIG. 9, the method for manufacturing substrate according to one embodiment of the present disclosure comprises:

depositing a second barrier layer film, a copper metallic layer film, a first barrier layer film and a connecting layer film in sequence on a base: as illustrated in FIG. 10a, depositing a second barrier layer film 200, a copper metallic layer film 300, a first barrier layer film 400 and a connecting layer film 500 in sequence on a base 100; wherein each of the second barrier layer film 200 and the first barrier layer film 400 can be made of molybdenum-niobium alloy (MoNb); the connecting layer film 500 can be made of at least one of silicon oxide (SiOx), silicon nitride (SiNx) and silicon oxynitride (SiON) or a combination thereof;

coating a layer of photoresist on the connecting layer film, and exposing and developing the photoresist: as illustrated in FIG. 10b, coating a layer of photoresist on the connecting layer film 500, and exposing and developing the photoresist, so that a patterned photoresist 60 is formed;

by taking the developed photoresist as a mask, performing a dry etching process on the connecting layer film so as to form a pattern of connecting layer; as illustrated in FIG. 10c, by taking the developed photoresist (i.e., the patterned photoresist 60) as a mask, performing a dry etching process on the connecting layer film 500 and forming a pattern of connecting layer 50;

peeling off the photoresist: as illustrated in FIG. 10d, peeling off the developed photoresist (i.e., the patterned photoresist 60);

by taking the pattern of connecting layer as a mask, performing a wet etching process on the second barrier layer film, the copper metallic layer film and the first barrier layer film and forming patterns of the second barrier layer, the copper metallic layer and the first barrier layer: as illustrated in FIG. 10e, by taking the pattern of connecting layer 50 as a mask, performing a wet etching process on the second barrier layer film 200, the copper metallic layer film 300 and the first barrier layer film 400 and forming patterns of the second barrier layer 20, the copper metallic layer 30 and the first barrier layer 40; and forming a pattern of insulating layer on the base formed with the pattern of connecting layer: as illustrated in FIG. 10f, forming a pattern of insulating layer 70 on the base 100 formed with the pattern of connecting layer 50; wherein at this time, the insulating layer 70 completely covers the second barrier layer 20, the copper metallic layer 30, the first barrier layer 40 and the connecting layer 50, thereby facilitating subsequent processes.

By now, the above-described substrate according to the embodiments of the present disclosure is completed.

At least one embodiment of the present disclosure further provides a display device comprising the above-described substrate. The display device can be any product or component having display function, such as a cell phone, a tablet PC, a television, a display, a laptop, a digital photo frame, a navigator and etc. Those skilled in the art would appreciate that the display device must have other essential components, details of which are omitted here and which are not construed as a limitation of the present disclosure. Implementing of the display device can be learnt by referring to the above embodiments of the substrate, details will not be elaborated herein.

The embodiments of the present disclosure provide a substrate, a method for manufacturing the same, and a display device. The substrate comprises a base, and a copper metallic layer and a first barrier layer disposed on the base in sequence, and further comprises a connecting layer provided on the first barrier layer, the connecting layer configured to connect the photoresist coated on the connecting layer and the first barrier layer. Since in the present disclosure a connecting layer is provided on the first barrier layer, the adherence between the first barrier layer and the photoresist can be improved, thereby solving the problem of ununiform pattern in the patterning process performed on the film layers on the substrate and improving the patterning effect.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201610136488.X filed on Mar. 10, 2016, the disclosure of which is hereby entirely incorporated by reference as a part of the present disclosure.

1. A substrate comprising a base, and a copper metallic layer and a first barrier layer disposed on the base in sequence, wherein the substrate further comprises:
a connecting layer positioned on the first barrier layer; the connecting layer is configured to connect photoresist coated on the connecting layer and the first barrier layer.

2. The substrate according to claim 1, further comprising:
a second barrier layer disposed between the base and the copper metallic layer.

3. The substrate according to claim 1, wherein the connecting layer is made of at least one of silicon oxide, silicon nitride, or silicon oxynitride.

4. The substrate according to claim 1, further comprising an insulating layer which covers the connecting layer.

5. The substrate according to claim 4, wherein the insulating layer is made of at least one of silicon oxide, silicon nitride, or silicon oxynitride.

6. The substrate according to claim 2, wherein the first barrier layer or the second barrier layer is made of molybdenum-alloy.

7. The substrate according to claim 1, wherein the copper metallic layer comprises at least one of a gate electrode, a source electrode, a drain electrode, a gate line, a data line, a cathode, an anode, or an electrode lead.

8. The substrate according to claim 2, wherein the connecting layer is made of at least one of silicon oxide, silicon nitride, or silicon oxynitride.

9. The substrate according to claim 2, further comprising an insulating layer which covers the connecting layer from above.

10. The substrate according to claim 3, further comprising an insulating layer which covers the connecting layer.

11. A method for manufacturing the substrate according to claim 1, comprising:
depositing a copper metallic layer film, a first barrier layer film and a connecting layer film in sequence on a base;
performing a patterning process on the copper metallic layer film, the first barrier layer film and the connecting layer film so as to form patterns of a copper metallic layer, a first barrier layer and a connecting layer; the connecting layer being configured to connect photoresist coated on the connecting layer and the first barrier layer.

12. The method according to claim 11, wherein forming patterns of a copper metallic layer, a first barrier layer and a connecting layer comprises:
coating a layer of photoresist on the connecting layer film, and exposing and developing the photoresist;
by taking the developed photoresist as a mask, performing a dry etching process on the connecting layer film so as to form a pattern of connecting layer, and peeling off the developed photoresist;
by taking the pattern of connecting layer as a mask, performing a wet etching process on the copper metallic layer film and the first barrier layer film so as to form patterns of the copper metallic layer and the first barrier layer.

13. The method according to claim 11, wherein forming patterns of a copper metallic layer, a first barrier layer and a connecting layer comprises:
coating a layer of photoresist on the connecting layer film, and exposing and developing the photoresist;
by taking the developed photoresist as a mask, performing a dry etching process on the connecting layer film so as to form a pattern of a connecting layer;
by taking the developed photoresist as a mask, performing a wet etching process on the copper metallic layer film and the first barrier layer film so as to form patterns of a copper metallic layer and a first barrier layer; and
peeling off the developed photoresist.

14. The method according to claim 11, wherein before depositing the copper metallic layer film on the base, the method comprises:
depositing a second barrier layer film on the base;
and after forming a pattern of copper metallic layer, the method further comprises:
performing a patterning process on the second barrier layer film so as to form a pattern of second barrier layer.

15. The method according to claim 14, wherein the patterns of the second barrier layer, the copper metallic layer and the first barrier layer are formed by one patterning process.

16. The method according to claim 11, further comprising:
forming a pattern of insulating layer on the base formed with the pattern of connecting layer.

17. The method according to claim 12, wherein before depositing the copper metallic layer film on the base, the method comprises:
depositing a second barrier layer film on the base;
and after forming a pattern of copper metallic layer, the method further comprises:
performing a patterning process on the second barrier layer film so as to form a pattern of second barrier layer.

18. The method according to claim 13, wherein before depositing the copper metallic layer film on the base, the method comprises:
depositing a second barrier layer film on the base;
after forming a pattern of copper metallic layer, the method further comprising:
performing a patterning process on the second barrier layer film so as to form a pattern of second barrier layer.

19. The method according to claim 12, further comprising:
forming a pattern of insulating layer on the base formed with the pattern of connecting layer.

20. A display device comprising the substrate according to claim 1.
